(19) United States
(12) Patent Application Publication
(10) Pub. No.: US 2024/0384389 A1
(43) Pub. Date: Nov. 21, 2024

(54) EVAPORATION MASK AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventors: Weilai LIU, Wuhan (CN); Liang SUN, Wuhan (CN); Qingjiang REN, Wuhan (CN); Sheng CHEN, Wuhan (CN)

(21) Appl. No.: 18/496,021

(22) Filed: Oct. 27, 2023

(30) Foreign Application Priority Data
May 18, 2023 (CN) 202310581126.1

(51) Int. Cl. C23C 14/04

(52) U.S. Cl. CPC C23C 14/042

(57) ABSTRACT

An evaporation mask includes a mask body and a support frame. The mask body includes a plurality of evaporation holes. The support frame is located on a first side of the mask body. The support frame includes a support body having an opening, disposed correspondingly to the plurality of evaporation holes. The opening extends along a thickness direction of the mask body and passes through two sides parallel to the first side of the support body. A composition material of the mask body comprises a metal, and a composition material of the support frame comprises at least one of silicon, sapphire, and silicon carbide.

### CROSS REFERENCE TO RELATED APPLICATION

This application claims the priority of Chinese Patent Application No. 202310581126.1, entitled “EVAPORATION MASK AND MANUFACTURING METHOD THEREOF”, filed on May 18, 2023, the disclosure of which is incorporated herein by reference in its entirety.

### FIELD OF THE DISCLOSURE

The present disclosure relates to a manufacturing technology of a display, and more particularly, to an evaporation mask and a manufacturing method thereof.

### BACKGROUND

An OLED (Organic Light Emitting Diode) display device has the advantages of light weight, thin thickness, bendability, large viewing angle range, etc. In recent years, in order to further improve the resolution of OLEDs, silicon-based OLEDs, also known as Micro OLEDs have been developed. The Micro OLED is a combination of semiconductor and OLED micro-display technology, which uses single crystal silicon as the substrate and integrates CMOS driver circuit. Accordingly, the Micro OLED could have a similar resolution level with a smaller display panel and thus has been widely used in augmented reality (AR) and virtual reality (VR).

Conventionally, high-resolution Micro OLED products are usually achieved by using FMMs (Fine Metal Mask) with small thickness precision graphics. The FMMs usually use laser welding method to weld the metal substrate to the metal shaping frame. However, in the process of welding the thinner metal substrate to the metal shaping frame, some issues, such as wrinkles, insufficient welding, and weak strength may occur and thus reduce the reliability of the Micro OLED products made by FMMs.

In summary, the conventional FMM for the preparation of silicon-based OLED may introduce the above issues, such as wrinkles, insufficient welding strength, and weak strength in the production process due to its high precision and small thickness. These issues lead to low reliability of the manufacturing process of the Micro OLED product and needs to be improved.

### SUMMARY

One objective of an embodiment of the present disclosure is to provide an evaporation mask and a manufacturing process thereof, to alleviate the above-mentioned unreliability issues of the manufacturing process of the Micro OLED product.

An embodiment of the present disclosure is directed to an evaporation mask. The evaporation mask includes a mask body and a support frame. The mask body includes a plurality of evaporation holes. The support frame is located on a first side of the mask body. The support frame includes a support body having an opening, disposed correspondingly to the plurality of evaporation holes. The opening extends along a thickness direction of the mask body and passes through two sides parallel to the first side of the support body. A composition material of the mask body comprises a metal, and a composition material of the support frame comprises at least one of silicon, sapphire, and silicon carbide.

Optionally, the support frame includes a first support frame and a second support frame. The first support frame is located on the first side of the mask body. A composition material of the first support frame comprises at least one of silicon, sapphire, and silicon carbide. The second support frame is located on one side of the first support frame facing away from the mask body. A composition material of the second support frame comprises one of silicon nitride and metal.

Optionally, the mask body comprises a first side and a second side placed oppositely. The evaporation holes extend along the thickness direction of the mask body and pass through the first side and the second side. The mask body further comprises a plurality of blind holes. A thickness direction of the blind holes is the same as the thickness direction of the mask body.

Optionally, the plurality of the blind holes are distributed on the first side and/or the second side.

Optionally, the plurality of blind holes are alternately distributed on the first side and the second side.

Optionally, the plurality of blind holes are evenly distributed on the first side, and the plurality of blind holes are evenly distributed on the second side.

Optionally, at least one of the blind holes is located between at least a set of adjacent two of the evaporation holes.

Optionally, the plurality of evaporation holes are arranged in the first and second directions. A plurality of the blind holes are arranged and connected along the second direction between adjacent two first sets of the evaporation holes arranged in the first direction to constitute a first groove, and a plurality of the blind holes are arranged and connected along the first direction between adjacent two second sets of the evaporation holes arranged in the second direction to constitute a second groove. The first set of the evaporation holes comprises a plurality of the evaporation holes arranged in the second direction, the second set of the evaporation holes comprises a plurality of the evaporation holes arranged along the first direction, and a plurality of the first grooves and a plurality of the second grooves are cross-arranged to constitute a network structure.

Optionally, the plurality of evaporation holes are arranged in the first and second directions. Some of the blind holes are positioned between two adjacent evaporation holes arranged along the first direction, and some of the blind holes are positioned between two adjacent evaporation holes arranged along the second direction, and a plurality of the blind holes are arranged along the first direction and the second direction.

Optionally, the mask body is ferromagnetic.

Another embodiment of the present disclosure is directed to a method for manufacturing an evaporation mask. The method includes: providing a mask body, comprising a plurality of evaporation holes, wherein a composition material of the mask body comprises metal; forming a support frame on a first side of the mask body, wherein the support frame comprises a support body, and the support body has an opening, and the opening is positioned correspondingly to the plurality of evaporation holes, extends along a thickness direction of the mask body and passes through two sides parallel to the first side of the support body. The composition material of the support frame comprises at least one of silicon, sapphire, and silicon carbide.

Optionally, the step of forming the support frame on the first side of the mask body comprises: forming the support frame on the first side of the mask body by a bonding process.

Optionally, the support frame includes a first support frame and a second support frame. The first support frame is located on the first side of the mask body. A composition material of the first support frame comprises at least one of silicon, sapphire, and silicon carbide. The second support frame is located on one side of the first support frame facing away from the mask body. A composition material of the second support frame comprises one of silicon nitride and metal.

Optionally, the mask body comprises a first side and a second side placed oppositely. The evaporation holes extend along the thickness direction of the mask body and pass through the first side and the second side. The mask body further comprises a plurality of blind holes. A thickness direction of the blind holes is the same as the thickness direction of the mask body.

Optionally, the plurality of the blind holes are distributed on the first side and/or the second side.

Optionally, the plurality of blind holes are alternately distributed on the first side and the second side.

Optionally, the plurality of blind holes are evenly distributed on the first side, and the plurality of blind holes are evenly distributed on the second side.

Optionally, at least one of the blind holes is located between at least a set of adjacent two of the evaporation holes.

Optionally, the plurality of evaporation holes are arranged in the first and second directions. A plurality of the blind holes are arranged and connected along the second direction between adjacent two first sets of the evaporation holes arranged in the first direction to constitute a first groove, and a plurality of the blind holes are arranged and connected along the first direction between adjacent two second sets of the evaporation holes arranged in the second direction to constitute a second groove. The first set of the evaporation holes comprises a plurality of the evaporation holes arranged in the second direction, the second set of the evaporation holes comprises a plurality of the evaporation holes arranged along the first direction, and a plurality of the first grooves and a plurality of the second grooves are cross-arranged to constitute a network structure.

Optionally, the plurality of evaporation holes are arranged in the first and second directions. Some of the blind holes are positioned between two adjacent evaporation holes arranged along the first direction, and some of the blind holes are positioned between two adjacent evaporation holes arranged along the second direction, and a plurality of the blind holes are arranged along the first direction and the second direction.

The present disclosure provides an evaporation mask and a manufacturing method thereof. The evaporation mask includes a mask body and a support frame. The mask body includes a plurality of evaporation holes. The support frame is located on a first side of the mask body. The support frame includes a support body having an opening, disposed correspondingly to the plurality of evaporation holes. The opening extends along a thickness direction of the mask body and passes through two sides parallel to the first side of the support body. A composition material of the mask body comprises a metal, and a composition material of the support frame comprises at least one of silicon, sapphire, and silicon carbide. By avoiding the use of metal materials to make a support frame to avoid fixing the support frame and the mask body by welding, the present disclosure could reduce the damage to the mask body, improves the life of the FMM, and improves the reliability of the Micro OLED product.

### BRIEF DESCRIPTION OF THE DRAWINGS

In order to more clearly illustrate the technical solution in the embodiment of the present disclosure, the following will be a brief introduction to the drawings required in the description of the embodiment. Obviously, the drawings described below are only some embodiments of the present disclosure, for those skilled in the art, without the premise of creative labor, may also obtain other drawings according to these drawings.

FIG. 1 is a cross-sectional view of an evaporation mask template according to an embodiment of the present invention.

FIG. 2 is a cross-sectional view of an evaporation mask template according to another embodiment of the present invention.

FIG. 3 is a top view of an evaporation mask template according to an embodiment of the present invention.

FIG. 4 is a top view of an evaporation mask template according to another embodiment of the present invention.

FIG. 5 is a top view of an evaporation mask template according to another embodiment of the present invention.

FIG. 6 is a cross-sectional view of an enlarged section of an evaporation mask template according to an embodiment of the present invention.

FIG. 7 is a cross-sectional view of an enlarged section of an evaporation mask template according to another embodiment of the present invention.

FIG. 8 is a flowchart of a method of forming an evaporation mask template according to an embodiment of the present invention.

FIG. 9 is a schematic diagram of the first scene of a method for manufacturing an evaporation mask according to an embodiment of the present invention.

FIG. 10 is a schematic diagram of the second scene of a method for manufacturing an evaporation mask according to an embodiment of the present invention.

FIG. 11 is a schematic diagram of the third scene of a method for manufacturing an evaporation mask according to an embodiment of the present invention.

FIG. 12 is a schematic diagram of the bonding process according to an embodiment of the present invention.

### DETAILED DESCRIPTION OF PREFERRED EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The following disclosure provides many different embodiments or examples to implement different structures of the present disclosure. In order to simplify the disclosure of the present disclosure, the components and settings of specific examples are described below. They are for example purposes only and are not intended to limit this application. Further, the present disclosure may repeat reference numbers and/or reference letters in different examples, such duplication is for the purpose of simplification and clarity, and does not by itself indicate the relationship between the various embodiments and/or settings discussed. Further, the present disclosure provides various examples of specific processes and materials, but those of ordinary skill in the art may be aware of the application of other processes and/or the use of other materials. The following are described in detail, it should be noted that the order of description of the following embodiments is not used as a qualification for the preferred order of embodiments.

In addition, it should be noted that the drawings only provide structures and/or steps that are closely related to the present invention, and some details that are not closely related to the invention are omitted. The purpose is to simplify the drawings and make the invention points clear at a glance. Either the actual devices and methods are shown or they are exactly the same as the drawings, and are not intended to be limitations of the actual devices and methods. Moreover, the enumeration of numerical values such as size, concentration, force, temperature, etc. in the present invention is only for distance description, but is not limited to the above-mentioned numerical values. The numerical values can be set according to the actual situation, as long as the corresponding effect is achieved.

The present disclosure provides an evaporation mask plate, which includes but is not limited to the following embodiments and combinations of the following embodiments.

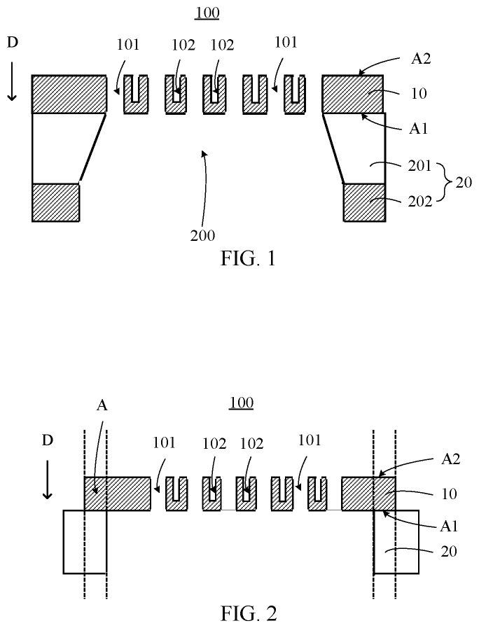

As shown in FIGS. 1-7, the evaporation mask 100 comprises a mask body 10 and a support frame 20. The mask body 1 comprises a first side A1 and a second side A2 positioned oppositely and has a plurality of evaporation holes 101. The evaporation holes 101 extend along the thickness direction D of the mask body 10 and pass through the first side A1 and the second side A2. The support frame 20 is located on the first side A1 of the mask body 10. The support frame 20 comprises a support body, which has an opening 200. The opening 200 is arranged correspondingly to the plurality of evaporation holes 101 (It can be understood that along the thickness direction of the mask body 10, the projection of a plurality of evaporation holes 101 falls into the projection of the opening 200), and extends along the thickness direction D of the mask body 10 and runs through both sides parallel to the first side A1 of the support body. The composition material of the support frame 20 comprises at least one of silicon, sapphire, and silicon carbide.

In this embodiment, the evaporation mask 100 further comprises a support frame 20 located on the first side A1 (may also be the second side A2) of the mask body 10. The support frame 20 provides an opening 200 corresponding to the evaporation holes 101 in the support body. The support body of the support frame 20 has a support function and is positioned correspondingly to the edge part (the actual structure) of the mask body 10. Accordingly, the support body could play a supporting and qualitative role for the mask body 10, and thus improve the production yield of the evaporation mask 100.

Conventionally, the composition material of the support frame is generally metal, and the mask body is usually welded to the metal shaping frame by laser welding. Due to the small thickness of the mask body, some issues, such as wrinkles, insufficient welding strength, too weak and easy to damage during the welding process, occur and thus the life of the evaporation mask reduces.

In this embodiment, the composition material of the support frame 20 comprises one of silicon, sapphire, and silicon carbide, and the support frame may also be made with a substrate for forming the mask body 10. That is, the support frame 20 may avoid the use of metal materials to avoid fixing the support frame 20 and the mask body 10 by welding. This could reduce the damage to the mask body 10, improve the life of the FMM and improve the reliability of the Micro OLED product.

The mask body 10 has ferromagnetism. Specifically, under the condition that the direction of evaporation is the same as the direction of gravity, it can be regarded that the magnetism of the mask body 10 and the metal material passing through the evaporation mask 100 is the same. Or, the ferromagnetic film layer with the same magnetism as the mask body 10 can be provided on the side of the evaporation mask 100 facing away from the evaporation source, so that there is a repulsion between the mask body 10 and the evaporated metal material, so as to reduce the risk of deformation of the mask body 10 along the evaporation direction (that is, the gravity direction). Under the condition that evaporation direction is opposite to the direction of gravity, it can be regarded that the magnetic properties of the mask body 10 and the metal material passing through the evaporation mask 100 are different. The ferromagnetic film layer with a different magnetism from the mask body 10 may be provided on the side of the evaporation mask 100 facing away from the evaporation source, so that the mask body 10 and the evaporated metal material have attraction to reduce the risk of deformation of the mask body 10 due to the gravity.

In one embodiment, as shown in FIG. 1, the support frame 20 comprises a first support frame 201 and a second support frame 202. The first support frame 201 is located on the first side A1 of the mask body 10, and the composition material of the first support frame 201 comprises at least one of silicon, sapphire, and silicon carbide. The second support frame 202 is located on the side of the first support frame 201 facing away from the mask body 10, and the composition material of the second support frame 202 comprises at least one of silicon nitride and metal. In this embodiment, the support frame 20 specifically comprises a first support frame 201 and a second support frame 202 positioned sequentially in the direction away from the mask body 10. The first support frame 201 close to the mask body 10 may be made of a substrate for forming the mask body 10, and the second support frame 202 away from the mask body 10 may be made of a material that prevents from being etched by an alkaline solution, such as one of silicon nitride and metal, thereby protecting the first support frame 201 so that a hole running through the first support frame 201 can be formed later.

In one embodiment, the mask body 10 is further provided with a plurality of blind holes 102. The thickness direction of the blind holes 102 is the same as the thickness direction D of the mask body 10. A plurality of evaporation holes 101 disposed on the mask body 10 may be for the evaporation material to pass through to form a corresponding component on a plurality of areas opposite the evaporation holes 101 of the corresponding substrate. The portion that is not the evaporation hole 101 in the mask body 10 may block the evaporation material from falling into the corresponding areas of the substrate. Specifically, the composition material of the evaporation mask 100 may include a metal. For example, Ferroalloy with Nickel in it may be used to form the mask body. The proportion of iron, nickel and carbon of the Ferroalloy can be respectively 63.8%, 36% and 0.2%.

In the process of using the evaporation mask 100 to perform an evaporation process, especially for the evaporation mask 100 with a small thickness, because the evaporation material passing through a plurality of evaporation holes 101 on the evaporation mask 100 will produce force, this force results in a deformation of the evaporation mask 100, so that the distance between a part of the evaporation mask 100 and the substrate changes. For example, it will cause the feathering phenomenon of the deformed part of the evaporation mask 100 to increase such that the corresponding part of the deposited pattern has a shadow effect, which reduces the reliability of the evaporation process.

In this embodiment, the mask body 10 has a plurality of blind holes 102 to form the evaporation mask 100. The plurality of blind holes 102 can be understood as grooving the surface of the mask body 10, and the portion of the mask body 10 may be dug out. In this way, the weight of the mask body 10 can be reduced, so that the evaporation mask 100 has a smaller weight. In addition, forming the plurality of blind holes 102 is equivalent to digging the mask body 10 so that the interior of the mask body 10 can be exposed. This releases the residual stress inside the mask body 10 and thus reduces the stress of the mask body 10. In summary, the present embodiment can effectively reduce the risk of deformation of the evaporation mask 100 during the evaporation process, thereby improving the reliability of the evaporation process.

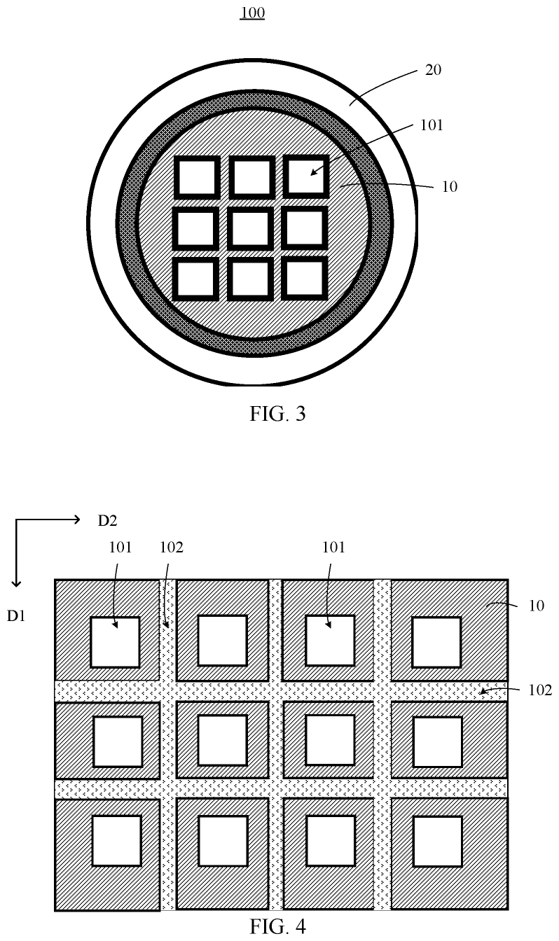

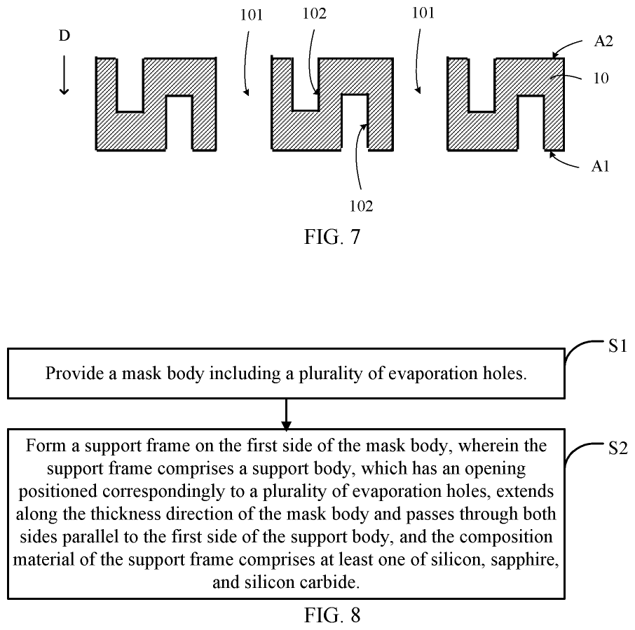

In one embodiment, as shown in FIGS. 1 to 7, the plurality of blind holes 102 are disposed in at least one of the first side A1 and the second side A2. FIGS. 1, 2 and 6 depict that a plurality of blind holes 102 are located on the first side A1. FIG. 3 (no blind hole 102 is shown) to 5 depict that a plurality of blind holes 102 are located on the first side A1 or the second side A2, FIG. 7 depicts a portion of the blind holes 102 disposed on the first side A1 and the other portion of the blind holes 102 disposed on the second side A2. In this embodiment, there is no limitation for the plurality of blind holes 102 to be located on the first side A1 or the second side A2. Because the blind holes 102 could can reduce the weight of the mask body 10 no matter they are located on the first side A1 or the second side A2, the evaporation mask 100 could have a small weight and the residual stress inside the mask body 10 could be reduced. Accordingly, the blind holes 102 located on the first side A1 or the second side A2 can effectively reduce the risk of deformation of the evaporation mask 100 during the evaporation process, thereby improving the reliability of the evaporation process.

In this embodiment, a plurality of blind holes 102 are located on the first side A1 or the second side A2, so that the blind vias 102 may extend in the thickness direction D of the mask body 10. On the one hand, since the plurality of blind holes 102 and the plurality of evaporation holes 101 extend along the thickness direction D of the mask template body 10, the plurality of blind holes 102 and the plurality of evaporation holes 101 can be formed by the same process, which improves the production efficiency of the evaporation mask 100. On the other hand, since the thickness of the mask body 10 is generally small, the first side A1 or the second side A2 has a larger area than the side with the smaller thickness in the mask body 10, locating the plurality of blind holes 102 on the first side A1 or the second side A2 could improve the production yield of the plurality of blind holes 102.

Furthermore, the plurality of blind holes 102 may be evenly distributed on the first side A1. Or, the plurality of blind holes 102 may also be evenly distributed on the second side A2. Or, the plurality of blind holes 102 may be distributed on the first side A1 and the second side A2, and these blind holes 102 are evenly disposed on the first side A1 and the second side A2. The present embodiment does not limit whether the plurality of blind holes 102 are distributed on the same side (the first side A1/the second side A2) as long as these blind holes 102 are evenly distributed on either side (the first side A1/the second side A2). This uniformity could avoid the blind holes 102 concentrating in a certain region, which may result in a low mechanical strength in this region and deformations or damages due to the low mechanical strength.

In one embodiment, as shown in FIGS. 1 to 7, at least one blind hole 102 is located between at least a set of adjacent two evaporation holes 101. FIGS. 1, 2, 4 and 5 only depict that a blind hole 102 is located between the adjacent two evaporation holes 101. FIGS. 6 and 7 depict that two blind holes 102 are located between the adjacent two evaporation holes 101. In the process of using the evaporation mask 100 to perform the evaporation process, when the evaporation material passes through a plurality of evaporation holes 101 on the evaporation mask 100, a force is generated. That is, it can be regarded that the adjacent two evaporation holes 101 will be subjected to the force brought by the corresponding two evaporation holes 101. Accordingly, the mask 101 might be to deform. In this embodiment, at least one blind hole 102 is provided between the adjacent two evaporation holes 101. In this embodiment, the blind hole(s) 102 between the adjacent two evaporation holes 101 may release the residual stress between the adjacent two evaporation holes 101. This could alleviate the deformation caused by stress and improve the application value of the blind hole 102.

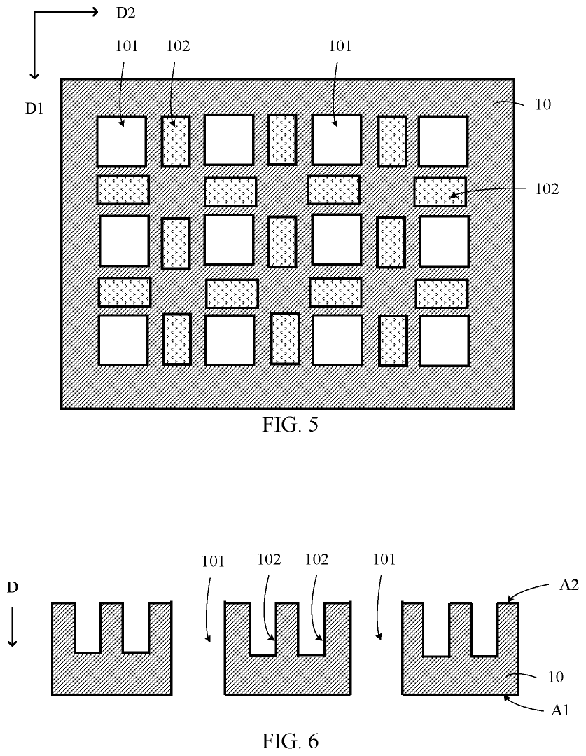

Unlike FIG. 5, for a plurality of evaporation holes 101 disposed consecutively, the blind hole 102 may be provided in the central region of the “plurality of evaporation holes 101 disposed consecutively.” For example, the blind hole 102 may be provided in the central region of the four evaporation holes 101 arranged in each array in FIG. 5. On one hand, it can be regarded that the blind hole 102 can simultaneously release the residual stresses between the “plurality of evaporation holes 101 continuously disposed” and thus optimize its ability to release stresses. On the other hand, it can be regarded that the blind hole 102 is not located between two adjacent evaporation holes 101, which can avoid the risk of deformation or even damage to the mask body 10 because the blind hole 102 is too close to the evaporation holes 101.

As shown in FIG. 4, a plurality of the evaporation holes 101 are arranged in the first direction D1 and the second direction D2. A plurality of the blind holes 102 arranged along the second direction D2 are provided between the adjacent two first sets of evaporation holes 101 arranged along the first direction D1 and connected to constitute a first groove. A plurality of blind holes 102 arranged and connected along the first direction D1 are provided between adjacent two second sets of evaporation holes 101 arranged along the second direction D2 to constitute a second groove. The first set of the evaporation holes 101 includes a plurality of evaporation holes 101 arranged along the second direction D2. The second set of a plurality of evaporation holes 101 comprises a plurality of evaporation holes 101 arranged along the first direction D1. A plurality of the first groove and a plurality of the second groove are cross-arranged to form a network structure.

Here, the first direction D1 is perpendicular to the second direction D2 as an example for illustration. A plurality of evaporation holes 101 are arranged in an array. Each first set of evaporation holes 101 includes a plurality of evaporation holes 101 located in the same row, and each second set of evaporation holes 101 includes a plurality of evaporation holes 101 located in the same column. In this embodiment, a first groove extending along the second direction D2 is provided between adjacent two first sets of evaporation holes 101 arranged along the first direction D1. For example, a first groove is provided between the adjacent two rows of evaporation holes 101, and a second groove extending along the first direction D1 is provided between the adjacent two second sets of evaporation holes 101 arranged along the second direction D2. For example, there is a second groove between the adjacent two columns of evaporation holes 101, i.e., a plurality of first grooves and a plurality of second grooves are arranged in a linear manner and form a network structure.

In this embodiment, a plurality of blind holes 102 form a network structure. The length of each groove of the blind holes 102 covers the length of the corresponding row or column of the evaporation holes 101. This can reduce the weight of the mask body 10 and release the internal stresses of the mask body 10. In this way, the risk of deformation of the evaporation mask 100 during the evaporation process can be effectively reduced, and the reliability of the evaporation process can be improved.

In one embodiment, as shown in FIG. 5, a plurality of evaporation holes 101 are arranged along the first direction D1 and the second direction D2. A blind hole 102 is provided between the adjacent two evaporation holes 101 arranged along the first direction D1. A blind hole 102 is provided between the adjacent two evaporation holes 101 arranged along the second direction D2. The plurality of the blind holes 102 are arranged along the first direction D1 and the second direction D2. Similarly, the first direction D1 is perpendicular to the second direction D2 as an example for illustration. In this way, a plurality of evaporation holes 101 are arranged in an array. In this embodiment, the blind holes 102 are provided between adjacent two evaporation holes 101 arranged in the first direction D1 and between adjacent two evaporation holes 101 arranged in the second direction D2. Accordingly, it can be regarded that a plurality of blind holes 102 are also arranged in an array.

In this embodiment, a plurality of blocky blind holes 102 are arranged in an array. This arrangement could evenly distribute the blind holes 102 and prevent the blind holes 102 from being too lengthy to reduce the hardness of the mask body 10 or the reliability of the evaporation mask 100.

According to an embodiment of the present disclosure, a method for manufacturing an evaporation mask is disclosed. The method comprises, but is not limited to, the following embodiments and a combination of the following embodiments.

In an embodiment, in conjunction with FIGS. 8 to 11, the method of manufacturing the evaporation mask may include, but is not limited to, the following steps:

Step S1: providing a mask body, including a plurality of evaporation holes, and the composition material of the mask body comprises metal.

The evaporation holes and the composition material of the mask body can be referred to the above disclosure.

Step S2: forming a support frame on the first side of the mask body, wherein the support frame comprises a support body, which has an opening positioned correspondingly to a plurality of evaporation holes, extends along the thickness direction of the mask body and passes through both sides parallel to the first side of the support body, and the composition material of the support frame comprises at least one of silicon, sapphire, and silicon carbide.

The composition materials of the support frame, the support body, the opening and the support body can be referred to the above disclosure.

Step S1 could further include Step S101 and Step S102.

Step 101: providing an initial mask body 01, including the first side B1 and the second side B2 positioned oppositely.

The initial mask body 01 may be a whole layer of film. The initial mask body 01 may have a small thickness. The first side A1 and the second side A2 can be two sides perpendicular to the thickness direction of the initial mask body 01. Here, the first side A1 and the second side A2 can be understood as the upper surface and lower surface of the initial mask body 01, respectively. The composition material and thickness of the initial mask body 01 can be referred to the above disclosure of the composition material and thickness of the mask body 10. For example, the initial mask body 01 may be ferroalloy with nickel in it.

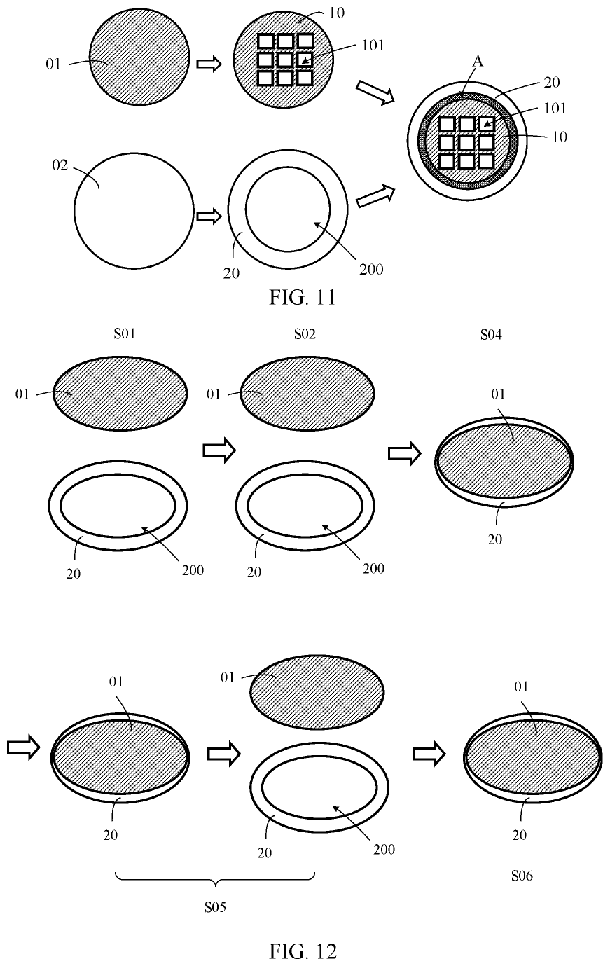

S102: processing the initial mask body 01 to form the mask body 10, wherein the mask body 10 has a plurality of evaporation holes 101 and a plurality of blind holes 102 (not shown in FIGS. 10 and 11), and the evaporation holes 101 extend along the thickness direction D of the mask body 10 and pass through the first side B1 and the second side B2.

The plurality of evaporation holes 101 here may be referred to the relevant disclosure above. The plurality of evaporation holes 101 on the mask body 10 could allow the evaporation material to pass through to form a corresponding component on the regions of the substrate corresponding to the evaporation holes 101. In the process of the evaporation process using evaporation mask 100, because a force is formed when the evaporation material passing through a plurality of evaporation holes 101 on the evaporation mask 100, this force may reduce the reliability of the evaporation process.

In this embodiment, a plurality of blind holes 102 disposed on the mask template body 10 can be understood as grooving the surface of the mask body 10. Compared with the mask body 10 before the grooving treatment, on the one hand, the weight of the mask body 10 can be reduced, so that the evaporation mask 100 has a smaller weight. On the other hand, a plurality of blind holes 102 are equivalent to digging the mask template body 10 so that the interior of the mask body 10 can be exposed. This releases the residual stress inside the mask body 10 and thus reduces the stress of the mask body 10. In summary, the present embodiment can effectively reduce the risk of deformation of the mask 100 in the process of evaporation process, thereby improving the reliability of the evaporation process.

As shown in FIG. 4 and FIG. 5, in this embodiment, a plurality of blind holes 102 may be arranged as multiple lines between a plurality of evaporation holes 101 (as shown in FIG. 4) or as blocks located between a plurality of evaporation holes 101 (as shown in FIG. 5). As shown in FIGS. 4 and 5, a blind hole 102 may be provided between the adjacent two evaporation holes 101. Or, as shown in FIGS. 6 and 7, two blind holes 102 may be provided between the adjacent two evaporation holes 101. Surely, the number of blind holes 102 between the adjacent two evaporation holes 101 may be set according to the distance between the adjacent two evaporation holes 101, the thickness of the mask body 10 and/or other factors. Further, as shown in FIG. 6, a plurality of blind holes 102 may be located on the second side A2. Or, as shown in FIG. 7, a plurality of blind holes 102 may be located on the second side A2 and the first side A1.

Step S102 comprises Step 1021 and Step 1022.

Step 1021: providing a support layer 02.

Step 1022: providing the initial mask body 01 on the support layer 02.

The thickness of the initial mask body 01 is comparatively small. The support layer 02 can play a supporting and shaping role on the initial mask body 01. In this embodiment, before placing the initial mask body 01 on the support layer 02, there is no limitation about whether to treat the support layer 02. It can be understood that at the time after placing the initial mask body 01 on the support layer 02, the initial mask body 01 is processed to form the mask body 10. Here, the composition materials of the support layer 02 can be referred to the above disclosure of the composition material of the support frame 20. For the following illustration, the composition material of the support layer 02 and the composition material of the support frame 20 include silicon as an example.

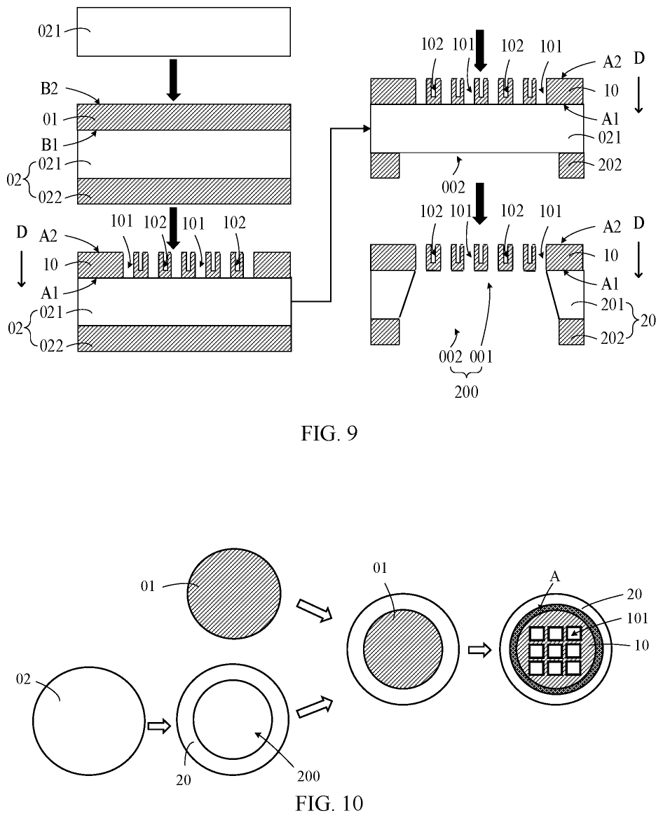

As shown in FIG. 9, the support layer 02 comprises a first support layer 021, a second support layer 022 located on a side of the first support layer 021 away from the initial mask body 01. Step S1022 comprises:

S10221: forming the initial mask body 01 by a sputtering process on the first support layer 021.

Step S2 comprises Step S201 and Step S202.

Step S201: forming a second opening 002 the second support layer 022 to form a second support frame 202.

The second opening 002 is disposed relative to the plurality of the evaporation holes 101, extends along the thickness direction D of the mask body 01 and passes through both sides of the second support layer 022 parallel to the first side A1.

Step S202: forming a first opening 001 on the first support layer 021 to form a first support frame 201.

The first opening 001 is disposed opposite to the second opening 002.

In this embodiment, the first support layer 021 is a silicon wafer as an example. Before Step S10221, a double-sided polishing could be performed on the first support layer 021 (silicon wafer), and the first support layer 021 (silicon wafer) can be cleaned. Specifically, the first support layer 021 (silicon wafer) is placed in a mixed solution at 75° C. and cleaned for 10 minutes. The recipe of the mixed solution could be: the ratio of deionized water, H₂O₂ solution with a concentration of 30%, and ammonia with a concentration of 25% can be 15:3:1. And then, the first support layer 021 (silicon wafer) is soaked in 50:1 HF solution and cleaned for 1 minute to remove the silica on the surface. And then, the first support layer 021 (silicon wafer) is cleaned in another mixed solution at 75° C. for 10 minutes. The recipe of the another mixture solution could be: the ratio of deionized water, H₂O₂ solution with a concentration of 30%, and hydrochloric acid (HCl) solution with a concentration of 37% can be 15:3:1. At last, the first support layer 021 (silicon wafer) is soaked in the deionized water for 5 minutes and then dried.

Step S10221 may form an initial mask body 01 on the upper side of the first support layer 021. Further, a second support layer 022 may also be formed on the lower side of the first support layer 021. The composition material of the second support layer 022 may be referred to the above disclosure of the composition material of the second support frame 202. In order to facilitate preparation, the same material can be used on the upper side and the lower side of the first support layer 021 to form the initial mask template body 01 and the second support layer 022 by sputtering process. The thicknesses of the initial mask body 01 and the second support layer 022 can be 2 um to 5 um, and the stress of the initial mask body 01 and the second support layer 022 can be 100 MPa to 200 MPa.

Based on the above, Step S102 may specifically be a step for performing an exposure process and a dry etching on the initial mask body 01. The exposure of the areas corresponding to a plurality of evaporation holes 101 and a plurality of blind holes 102 in the initial mask body 01 may be performed by the same halftone lithographic mask, or it can be divided into two different groups of lithographic masks. When the evaporation mask 100 comprising the mask body 10 is used to evaporate the organic light-emitting material by the evaporation process to form sub-pixels, the diameter of the evaporation hole 101 may be made small enough to form a sub-pixel with a diameter of less than 10 um.

In Step S2, by the exposure and the dry etching processes or laser etching, a second opening 002 corresponding to a plurality of evaporation holes 101 could be formed on the second support layer 022 to form a second support frame 202. As the above, the second opening 002 and the first opening 001 may constitute the aforementioned opening 200. Here, the size of the two openings may not be smaller than the size of the pixel display area for carrying plurality of sub-pixels. Furthermore, the component with the formed second support frame 202 may be soaked in a KOH solution with a concentration of 20% for wet etching to remove the portion of the first opening 001 on the first support layer 021 to form the first support frame 201 positioned correspondingly to the second opening 002.

The support frame is formed on the first side of the mask body by the bonding process and the related operations could be referred to the following embodiment.

In one embodiment, as shown in FIG. 10, Step 1022 comprises Step S10222 and Step S10223.

Step S10222: forming an opening 200 on the support layer 02 to form a support frame 20.

The opening 200 is disposed correspondingly to the plurality of the evaporation hole 101, extends along the thickness direction D of the mask body 10 and passes through both sides parallel to the first side A1 in the support layer 02 (e.g., the upper side or lower side perpendicular to the thickness direction D of the mask body 10).

Step S10223: positioning the initial mask body 01 on the support frame 20 by a bonding process.

In Step S10222, the support frame 20 having the opening 200 (e.g., may be in the shape of a torus) may be formed by, but not limited to, a laser cutting. The thickness of the support frame 20 may be 500 microns to 725 microns. Similarly, when the evaporation mask 100 comprising the mask body 10 is used to evaporate the organic luminescent material by the evaporation process to form sub-pixels, the diameter of the evaporation hole 101 may be made small enough to form a sub-pixel with a diameter less than 10 μm, and the size of the opening 200 may not be smaller than the size of the pixel display area for carrying a plurality of sub-pixels. The thickness of the support frame 20 may be 500 microns to 725 microns. In this embodiment, the thickness of the initial mask body 01 may be 5 μm to 8 μm, and the width of the overlapped region A of the mask body 10 and the support frame 20 is 5 mm to 10 mm.

After Step S10222, an exposure process and a dry etching process could be performed on the initial mask body 01 to form the mask body 10.

In one embodiment, as shown in FIG. 11, the method could further comprise:

Step S301: providing a support layer 02.

In addition, after Step S102, the method could comprise, but not limited to, the following step:

Step S302: providing the mask body 10 on the support layer 02 by the bonding process.

Specifically, compared with the above disclosure of the embodiment shown in FIG. 10, the difference between this embodiment and the embodiment shown in FIG. 10 is that, in this embodiment, the initial mask body 01 is first exposed and dry etched to form the mask body 10, then an opening 200 formed on the support layer 02 to form a support frame 20, and then the mask body 10 is disposed on the support layer 02 by the bonding process. The thickness of the support frame 20 may be 500 microns to 725 microns, the thickness of the initial mask body 01 may be 5 μm to 8 μm, and the width of the overlapped region A the mask body 10 and the support frame 20 is 5 mm to 10 mm.

Step S10223 can be understood as performing a first pretreatment, cleaning, visual alignment on the support frame 20 and the initial mask body 01 to be bonded and then realize the bonding of the two by different methods. After the support frame 20 and the initial mask body 01 are bonded, the atoms of the interface of the support frame 20 and the initial mask body 01 are reacted by external forces to form a covalent bond, and the bonded interface reaches a specific bonding strength. As shown in FIG. 12, the bonding of the support frame 20 and the initial mask body 01 bonding are illustrated as an example. The bonding process may include, but are not limited to, the Steps S01-S07.

Step S01: bombard the surfaces to be bonded with a Si-containing Ar ion beam at a vacuum level of 10-6 Pa (here, the surfaces to be bonded by include both the surfaces of the support frame 20 and the initial mask template body 01 to be bonded).

Step S02: transferring the support frame 20 and the initial mask body 01 to a chamber with a vacuum degree of 10-2 Pa, filling the chamber with N2 containing moisture to make the pressure reach 3 KPa, and then filling the chamber with dry N2 to make the pressure reach the atmospheric pressure.

Step S03: removing the support frame 20 and the initial mask body 01 and wash them with water and then spinning dry them in the N2 environment.

Step S04: performing a pre-bonding on the support frame 20 and the initial mask body 01.

That is, in the air environment with no pressure and relative humidity of 40%, the support frame 20 and the initial mask body 01 are in contact with each other and maintained for more than 10 min.

Step S05: loading the pre-bonded contact support frame 20 and the initial mask plate body 01 into the bonding chamber, and using an adsorption chuck to separate the pre-contact support frame 20 and the initial mask plate body 01 in the chamber with a vacuum degree of 10-2 Pa.

Step S06: performing the bonding operation under 200° C., 2.5 MPa for 30 minutes.

Step S07: performing an anneal for 2 hours.

Accordingly to an embodiment of the present disclosure, a method for manufacturing a display panel is disclosed. The method comprises, but not limited to, the following embodiments and a combination of the following embodiments.

In one embodiment, the method comprises Step 101 and Step 102.

Step 101: providing an array substrate, comprising a plurality of first electrode portions.

Step 102: performing an evaporation process by any aforementioned evaporation mask or by an evaporation mask manufactured by any of the aforementioned manufacturing methods, to form a corresponding light-emitting portion on each of the first electrode portions.

Specifically, a plurality of first electrode portions may be an anode or cathode portion corresponding to a plurality of light-emitting parts. A whole and continuous cathode layer or anode layer may be provided on a side of the light-emitting portion away from the plurality of first electrode portions.

In one embodiment, Step S102 comprises S1021 and S1022.

S1021: placing the array substrate correspondingly to the evaporation mask.

S1022: proving an auxiliary layer on the side of the array substrate away from the evaporation mask, wherein the auxiliary layer provides the evaporation mask with a force directed to the array substrate.

It is understood that in this embodiment, the auxiliary layer is provided on the side of the array substrate away from the evaporation mask to provide the evaporation mask with a force directed to the array substrate. This can effectively improve the process of evaporation process. Because a force is formed when the evaporation material passes through a plurality of evaporation holes 101 on the evaporation mask 100, this force may make the evaporation mask 100 protrude away from the array substrate. Here, the auxiliary layer can provide the evaporation mask template with an opposite force directed to the array substrate, so as to reduce the protrusion degree of the evaporation mask 100. Thus, it can improve the reliability of the evaporation process. Here, the auxiliary layer may use, but not limited to, a magnetic adsorption force to provide the evaporation mask template with a force directed to the array substrate.

The present disclosure provides an evaporation mask and a manufacturing method thereof. The evaporation mask includes a mask body and a support frame. The mask body includes a plurality of evaporation holes. The support frame is located on a first side of the mask body. The support frame includes a support body having an opening, disposed correspondingly to the plurality of evaporation holes. The opening extends along a thickness direction of the mask body and passes through two sides parallel to the first side of the support body. A composition material of the mask body comprises a metal, and a composition material of the support frame comprises at least one of silicon, sapphire, and silicon carbide. By avoiding the use of metal materials to make a support frame to avoid fixing the support frame and the mask body by welding, the present disclosure could reduce the damage to the mask body, improves the life of the FMM, and improves the reliability of the Micro OLED product.

The above is a display device provided by an embodiment of the present disclosure is described in detail, and a specific example is applied herein to explain the principle and embodiment of the present disclosure, and the description of the above embodiment is only used to help understand the method of the present disclosure and its core ideas. At the same time, for those skilled in the art, according to the idea of the present disclosure, there will be changes in the specific embodiment and the scope of application, in summary, the content of this specification should not be understood as a restriction on the present disclosure.

What is claimed is:

1. A evaporation mask, comprising:
a mask body, comprising a plurality of evaporation holes; and
a support frame, located on a first side of the mask body, the support frame comprising:
a support body, having an opening, disposed correspondingly to the plurality of evaporation holes, wherein the opening extends along a thickness direction of the mask body and passes through two sides parallel to the first side of the support body;
wherein a composition material of the mask body comprises a metal, and a composition material of the support frame comprises at least one of silicon, sapphire, and silicon carbide.

2. The evaporation mask of claim 1, wherein the support frame comprises:
a first support frame, located on the first side of the mask body, wherein a composition material of the first support frame comprises at least one of silicon, sapphire, and silicon carbide; and
a second support frame, located on one side of the first support frame facing away from the mask body, wherein a composition material of the second support frame comprises one of silicon nitride and metal.

3. The evaporation mask of claim 1, wherein the mask body comprises a first side and a second side placed oppositely, the evaporation holes extend along the thickness direction of the mask body and pass through the first side and the second side; and the mask body further comprises a plurality of blind holes;
wherein a thickness direction of the blind holes is the same as the thickness direction of the mask body.

4. The evaporation mask of claim 3, wherein the plurality of the blind holes are distributed on the first side and/or the second side.

5. The evaporation mask of claim 4, wherein the plurality of blind holes are alternately distributed on the first side and the second side.

6. The evaporation mask of claim 4, wherein the plurality of blind holes are evenly distributed on the first side, and the plurality of blind holes are evenly distributed on the second side.

7. The evaporation mask of claim 3, wherein at least one of the blind holes is located between at least a set of adjacent two of the evaporation holes.

8. The evaporation mask of claim 7, wherein the plurality of evaporation holes are arranged in the first and second directions;
wherein a plurality of the blind holes are arranged and connected along the second direction between adjacent two first sets of the evaporation holes arranged in the first direction to constitute a first groove, and a plurality of the blind holes are arranged and connected along the first direction between adjacent two second sets of the evaporation holes arranged in the second direction to constitute a second groove; and
wherein the first set of the evaporation holes comprises a plurality of the evaporation holes arranged in the second direction, the second set of the evaporation holes comprises a plurality of the evaporation holes arranged along the first direction, and a plurality of the first grooves and a plurality of the second grooves are cross-arranged to constitute a network structure.

9. The evaporation mask of claim 7, wherein the plurality of evaporation holes are arranged in the first and second directions;
wherein some of the blind holes are positioned between two adjacent evaporation holes arranged along the first direction, and some of the blind holes are positioned between two adjacent evaporation holes arranged along the second direction, and a plurality of the blind holes are arranged along the first direction and the second direction.

10. The evaporation mask of claim 1, wherein the mask body is ferromagnetic.

11. A method for manufacturing an evaporation mask, the method comprising:
providing a mask body, comprising a plurality of evaporation holes, wherein a composition material of the mask body comprises metal;
forming a support frame on a first side of the mask body, wherein the support frame comprises a support body, and the support body has an opening, and the opening is positioned correspondingly to the plurality of evaporation holes, extends along a thickness direction of the mask body and passes through two sides parallel to the first side of the support body; and the composition material of the support frame comprises at least one of silicon, sapphire, and silicon carbide.

12. The method of claim 11, wherein the step of forming the support frame on the first side of the mask body comprises:
forming the support frame on the first side of the mask body by a bonding process.

13. The method of claim 11, wherein the support frame comprises:
a first support frame, located on the first side of the mask body, wherein a composition material of the first support frame comprises at least one of silicon, sapphire, and silicon carbide; and
a second support frame, located on one side of the first support frame facing away from the mask body, wherein a composition material of the second support frame comprises one of silicon nitride and metal.

14. The method of claim 11, wherein the mask body comprises a first side and a second side placed oppositely, the evaporation holes extend along the thickness direction of the mask body and pass through the first side and the second side; and the mask body further comprises a plurality of blind holes;
wherein a thickness direction of the blind holes is the same as the thickness direction of the mask body.

15. The method of claim 14, wherein the plurality of the blind holes are distributed on the first side or the second side.

16. The method of claim 15, wherein the plurality of blind holes are alternately distributed on the first side and the second side.

17. The method of claim 15, wherein the plurality of blind holes are evenly distributed on the first side; and/or the plurality of blind holes are evenly distributed on the second side.

18. The method of claim 14, wherein at least one of the blind holes is located between at least a set of adjacent two of the evaporation holes.

19. The method of claim 18, wherein the plurality of evaporation holes are arranged in the first and second directions;
wherein a plurality of the blind holes are arranged and connected along the second direction between adjacent two first sets of the evaporation holes arranged in the first direction to constitute a first groove, and a plurality of the blind holes are arranged and connected along the first direction between adjacent two second sets of the evaporation holes arranged in the second direction to constitute a second groove; and
wherein the first set of the evaporation holes comprises a plurality of the evaporation holes arranged in the second direction, the second set of the evaporation holes comprises a plurality of the evaporation holes arranged along the first direction, and a plurality of the first grooves and a plurality of the second grooves are cross-arranged to constitute a network structure.

20. The method of claim 18, wherein the plurality of evaporation holes are arranged in the first and second directions;
wherein some of the blind holes are positioned between two adjacent evaporation holes arranged along the first direction, and some of the blind holes are positioned between two adjacent evaporation holes arranged along the second direction, and a plurality of the blind holes are arranged along the first direction and the second direction.
